(19) United States
(12) Patent Application Publication
(10) Pub. No.: US 2026/0267040 A1
(43) Pub. Date: Sep. 10, 2026

(54) GRAPHENE-INTEGRATED PLASMONIC METASURFACE ARRAY

(71) Applicant: CARNEGIE MELLON UNIVERSITY, Pittsburgh, PA (US)

(72) Inventors: Sheng Shen, Pittsburgh, PA (US); Xiu Liu, Pittsburgh, PA (US); Yibai Zhong, Pittsburgh, PA (US)

(73) Assignee: CARNEGIE MELLON UNIVERSITY, Pittsburgh, PA (US)

(21) Appl. No.: 19/549,617

(22) Filed: Feb. 25, 2026

Related U.S. Application Data
(60) Provisional application No. 63/767,306, filed on Mar. 5, 2025.

(51) Int. Cl. G02B 5/00; G02B 1/00; G02F 1/01; H10D 30/60; H10D 62/83; H10D 80/20

(52) U.S. Cl. CPC G02B 5/008; G02B 1/002; G02F 1/0147; H10D 30/60; H10D 62/83; H10D 80/251; G02F 2203/10

(57) ABSTRACT

Disclosed herein is an electrically programmable plasmonic metasurface array integrated with graphene field effect transistors and a method for producing highly dynamic, pixelated modulations of coherent mid-infrared emission using the device.

### RELATED APPLICATIONS

This application claims the benefit of U.S. Provisional Patent Application No. 63/767,306 filed Mar. 5, 2025, the contents of which are hereby incorporated herein in their entirety.

### GOVERNMENT RIGHTS

This invention was made with United States Government support under contracts HDTRA1-19-1-0028 and HDTRA1-26-1-0003, awarded by the Defense Threat Reduction Agency (DTRA) and contract 1931964 awarded by the National Science Foundation (NSF). The U.S. Government has certain rights in the invention.

### BACKGROUND

Active metasurfaces consist of planar arrays of subwavelength light scatters or antennas (“meta-atoms”). They enable dynamic and versatile control over electromagnetic field states and optical responses. Compared to conventional bulk optics, they feature ultra-compact, lightweight, and energy-efficient systems, which are particularly promising for applications constrained by a lean size, weight, or power budget, such as aerospace remote sensing, free-space communication, and point-of-care and wearable health monitoring. The high-density meta-atoms have degrees of freedom that facilitate real-time beam shaping and steering for devices including light detection and ranging (LiDAR) in autonomous vehicles and light-field display in augmented/virtual reality (AR/VR) modules. However, compared with their passive counterparts, the extra complexity for post-fabrication tunability introduced in active metasurfaces poses notable technical challenges for implementing these advanced functions, particularly in the mid-infrared regime due to the dearth of rational materials and device designs. For instance, subwavelength-scaled arrays of narrow-bandgap semiconductors suffer from costly crystal growth and require external cooling, impeding the miniaturized device integration. The dynamic switching of phase-change metasurfaces is typically limited to a dichotomy between metallic and dielectric states, while multistate phase transition encounters a narrow working window to attain critical temperatures.

Recent advances in thermal photonics reveal a new route for achieving dynamic light control in the mid-infrared range. The metasurface-augmented polaritonic and photonic modes, including surface plasmon polaritons from plasmonic metals, surface phonon polaritons from polar dielectrics and photonic crystals and their twisted bilayers, show strong temporal, spatial, or polarized coherence (i.e., narrowband, directional, or polarized emission). These modes can be unified to engineer the photonic density of states DOS for the thermal infrared emission intensity, formulated as:

$$I = E ( ω , T ) \cdot DOS ( ω , \hat{n} , \hat{p} ) \qquad ( 1 )$$

where:
ω is the frequency;
E is the average energy per photon ℏω/(e^{ℏω/k}^{_{B}}^{T}−1) at temperature T;
\hat{n} is the normal vector of direction; and
\hat{p} is the polarization vector.

Based on Eq. (1), two modulation schemes can be identified. The first involves the average photon energy E, which can be controlled by temperature T, whereas the second pertains to the photonic density of states DOS, which corresponds to emissivity, a far-field term normalized to an ideal blackbody commonly employed in radiometry.

To date, various methods have been employed to actively excite thermal infrared metasurfaces, such as thermal hot plate, mechanical actuation, and optical laser pulse. However, the realization of electrically programmable on-chip integration for large-area pixelated 2D arrays remains a significant challenge. Single-pixel active metasurfaces, by electrically modulated refractive indices of materials like graphene and transparent conductive oxides (indium silicon oxide, indium tin oxide), typically yield limited infrared emissivity contrast. Joule heating in an incandescent metasurface with a fixed resistance restricts the pixel modulation to binary on/off states and imposes constraints on the available design parameters for coherent characteristics due to the overlap of electrodes with optically active regions. Although state-of-the-art research has predominantly featured in-plane fan-out writing designs for 1D arrays, electrically driven 2D pixelated metasurfaces have rarely been demonstrated due to the complexities of electrical addressing.

### SUMMARY OF THE INVENTION

Due to its carbon nature and strong covalent bonding, graphene is stable at elevated temperatures and durable in long working cycles, and can function as a robust, transparent, high-speed, and tunable microheater. The atomically thin single-layer graphene acts as a broadband transparent electrode from visible to far-infrared, whose time constant for Joule heating can reach picoseconds. More importantly, the semi-metallic nature of graphene allows a fine-tuning of its carrier density by electrostatic gating, allowing for tunable microscale localized heating. Based on this spatial temperature modulation, disclosed herein as one aspect of the invention is an integrated emissivity-temperature scheme to create an electrically programmable 2D-pixelated mid-infrared metasurface, where emissivity control and temperature regulation are achieved by tuning heating position and strength, respectively.

The disclosed metasurface enables pixelated modulation of coherent thermal emission from an electrical-programmable plasmonic metasurface integrated with a graphene field-effect transistor (Gr-FET). The broadband transparency of single-layer graphene enables customized control over plasmonic meta-atoms fulfilling the design space for controlling mid-infrared coherent states across a wide range of wavelengths, directions, and polarizations. The spatial temperature modulation generated by the Gr-FET is effectively synergized with emissivity control by the localized surface plasmon polaritons (LSPs) from nanoantennas, preferably gold nanoantennas. This integrated temperature-emissivity modulation is systematically extended to form a pixelated 2D array, signifying an advanced approach toward scalable 2D electrical wiring for densely packed, individually addressable pixels.

Specifically, in one exemplary embodiment, a 3×3 sweeping pixel array demonstrates diverse alphanumeric displays, supported by an explicit analytical model detailing the control mechanism. The method, disclosed herein as a second aspect of the invention, offers superior potential in large-area scalability. For example, to independently control an N×N pixel array, only 2N+1 electrical pins are required, rather than N² pins. The small thermal mass from the ultrathin graphene film further enables rapid modulation, achieving a 3-dB bandwidth of 146 kHz in a total 95 μm×95 μm device. In conjunction with CMOS-compatible fabrication and high temperature resilience of large-area graphene grown by chemical vapor deposition (CVD), our device represents a significant stride in the development of next-generation mid-infrared active metadevices.

Some embodiments extend from local LSPs to nonlocal plasmonic quasi-bound states in the continuum (P-QBICs) for the metasurface pixel design. The P-QBIC exhibits reduced spectral bandwidth and emitting angle spreading relative to the LSP mode, indicating both enhanced temporal and spatial coherence, respectively.

Some embodiments include a dual-gate pixel architecture incorporating pull-up transistors to significantly reduce crosstalk, overcoming the fundamental limitation imposed by zero-bandgap graphene. The pin number becomes 2N+1 but is still much smaller than N².

Some embodiments may include addressable pixelated active metasurfaces with separated local gate electrodes for each pixel. In some embodiments, each individual pixel may include a center heating Gr-FET (heater) with metasurfaces deposited on the top, and four “L” shaped PU Gr-FETs encircling the heater. In some embodiments an active metadevice may be integrated with a custom-designed printed circuit broad (PCB).

### BRIEF DESCRIPTION OF THE DRAWINGS

By way of example, specific exemplary embodiments of the disclosed system and method will now be described, with reference to the accompanying drawings, in which:

FIG. 1 is a schematic representation of an exemplary 3×3 pixelated MIM active metasurface driven by graphene field-effect transistors (Gr-FETs).

FIG. 2 is a SEM image of the exemplary device of FIG. 1 at two different scales.

FIG. 3 is a graph showing wavelength emitted by the device as the surface area of the nanosquares varies.

FIG. 4A is a SEM image of 2 pixels comprised of perpendicular nanorods with distinct lengths on a single graphene channel. The zoom-in images (scale bar: 1 μm) illustrate the upper pixel with a longitudinal edge of 1 μm along the x-axis and the lower pixel with a longitudinal edge of 700 nm along the y-axis.

FIG. 4B is a graph showing the measured emissivity spectra of the upper and lower pixels with polarization angles of φ=90° and 0° respectively.

FIG. 4C is a polar plot showing the measured emissivity peaks across the polarization angles from 0° to 180°.

FIG. 5A is SEM image of the P-QBIC pixel (scale bar: 30 μm) with the inset showing its elliptical meta-atom array (scale bar: 5 μm).

FIG. 5B is a graph showing non-polarized Fourier-transform infrared spectroscopy (FTIR) spectra of the P-QBIC and LSP modes.

FIG. 6A is a graph showing non-polarized FDTD spectra of the P-QBIC and LSP modes.

FIG. 6B is a simulated emissivity mapping of wavelength and polar angle θₓ.

FIG. 7A is a graph showing the angular distribution with fixed wavelengths, and the spectral distribution with fixed θₓ.

FIG. 7B is a simulated emissivity mapping in direction cosines (uₓ, u_{y}) for the resonant wavelengths of the P-QBIC and LSP modes in FIG. 6A, respectively.

FIG. 8A is a graph of the polarized spectra of the P-QBIC and LSP modes.

FIG. 8B is a graph showing polarized FDTD spectra of the P-QBIC and LSP modes with different thicknesses of the Al₂O₃ spacer.

FIG. 9A is a graph showing a preliminary sweep of drain current versus gate voltage under a constant drain voltage where the source electrode is grounded.

FIG. 9B is a graph showing local resistivity along the graphene channel under different gate voltages, wherein the vertical dashed lines represent the positions of maximum local resistivity and the grey shaded areas represent regions outside the graphene channel.

FIG. 10A is a SEM image (scale bar: 50 μm) showing two pixels with the same resonant emissivity on a single bottom gate electrode.

FIGS. 10B-10D show continuous spatial temperature modulation under V_{d}=30 V. Thermal mapping images (scale bars: 50 μm) exhibit the hot spot control by aligning V_{g}. The dash lines indicate the Dirac point positions x₀.

FIG. 11A is an image (scale bar: 5 cm) of a custom-designed printed circuit board (PCB)-integrated active metasurface system.

FIG. 11B is a magnified image (scale bar: 25 μm) of an exemplary 3×3 pixelated 2D metasurface array, accompanied by a schematic depiction of wire bonding.

FIG. 12A is a sweep mapping of I_{d2}−(V_{g1}, V_{g2}) under V_{g1}=50 mV where the 3rd gate is grounded.

FIG. 12B is a thermal mapping image (scale bar: 25 μm) under three gate voltages.

FIG. 12C is a thermal mapping image (scale bar: 25 μm) of individual frames displaying the letter “L”.

FIG. 13A is a graph showing gate-voltage modulation at various times.

FIG. 13B is a graph showing source-drain-voltage on/off modulation at various times.

FIG. 14A are thermoreflectance mapping frames of the gate voltage modulation of FIG. 13A.

FIG. 14B are thermoreflectance mapping frames of the source-drain-voltage on/off modulation of FIG. 13B.

FIG. 15A is a schematic representation of dual-gate controlled Gr-FET pixels, wherein the pixels are connected in parallel with shared source line (V_{S}) and drain line (V_{D}) and further wherein four L-shaped pull-up (PU) transistors are located at the four corners and the square-shaped heating Gr-FET (heater) is located at the pixel center.

FIG. 15B is a simplified circuit diagram of the device of FIG. 15A.

FIG. 15C shows the operating scheme of a dual-gate pixel with PUs having larger intrinsic resistance than the heater.

FIG. 16A is an optical microscope image (scale bar: 20 μm) of a one-by-two pixel array.

FIGS. 16B-16E are temperature distributions measured via IR thermal mapping under different on/off V_{GS} combinations with constant V_{DS}=5 V.

### DETAILED DESCRIPTION

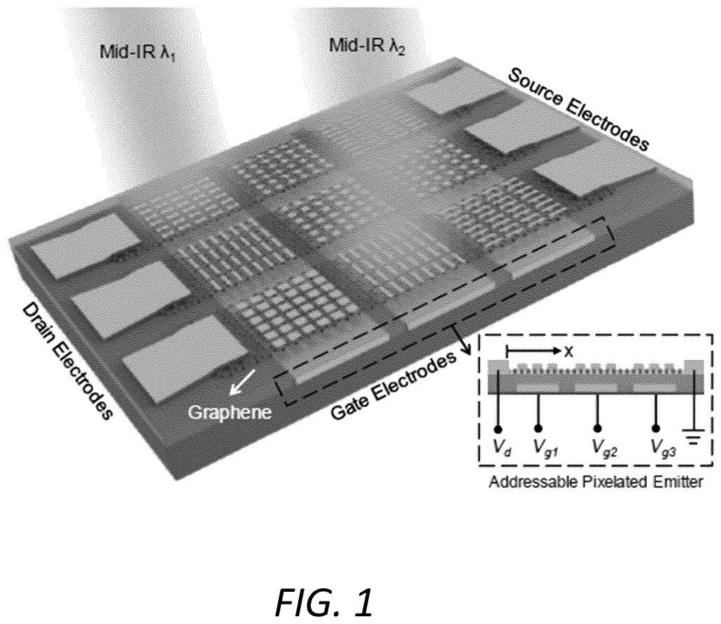

Integrated Emissivity-Temperature Active Metasurfaces-Disclosed herein is a design for and a method of fabricating pixelated active metasurfaces electrically driven by Gr-FETs, an example of which is schematically shown in FIG. 1. Each pixel comprises an array of gold (Au) plasmonic nanoantennas that either directly interfaces with a single-layer graphene channel or is separated from it by an aluminum oxide (Al₂O₃) dielectric layer (the schematic shows the direct-contact case), for coherent mid-infrared emission (with wavelengths λ₁, λ₂). The graphene layer is patterned and fabricated into Gr-FETs with source and drain contacts made of Au. The beneath layers of Al₂O₃ and Au serve as the gate dielectric and spacer, and the gate electrode and mirror for the Gr-FET and metal-insulator-metal (MIM) metasurface, respectively.

The Al₂O₃ layer is also co-optimized as the spacer of the MIM metasurface to achieve critical coupling. The Gr-FET structure provides a tunable and programmable Joule heating channel to modulate the spatial temperature distribution of metasurfaces. The source/drain and bottom gate electrodes of Gr-FETs are further patterned to allow for spatial temperature modulation in an addressable pixelated mode. The inset of FIG. 1 shows an addressable pixelated mode under a source-drain voltage Va with a patterned gate electrode assigning one gate voltage (V_{g1}, V_{g2} or V_{g3}) to each pixel.

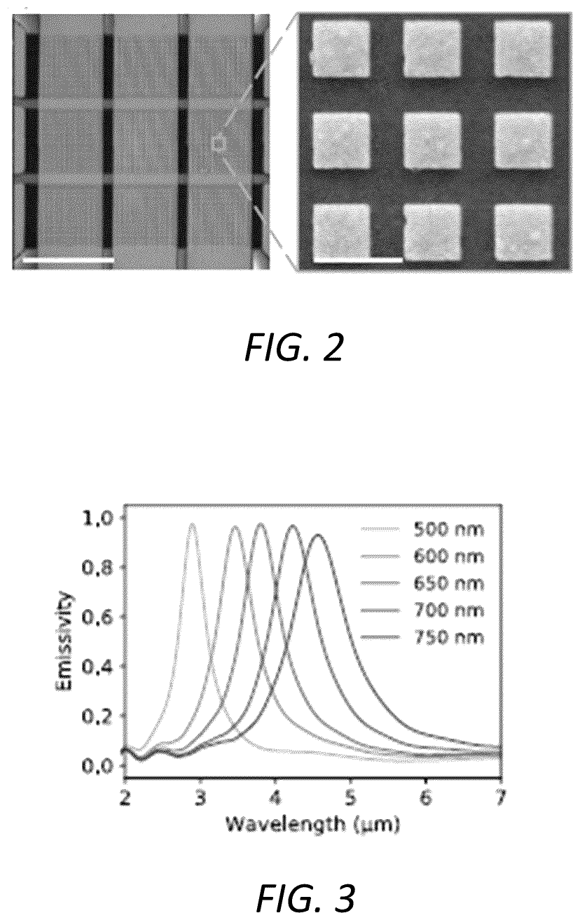

FIG. 2 is a scanning electron microscope (SEM) image (scale bar: 35 μm) of the fabricated active metadevice with its zoom-in image (scale bar: 800 nm) revealing the nanosquare meta-atoms with an edge length of 500 nm. In FIG. 2, the active pixelated metadevice is fabricated using hybrid optical and electron lithography processes (explained later herein). The zoomed-in image shows a typical Au nanosquare-based MIM metasurface in which the localized surface polariton (LSP) mode supports the narrowband emission at a wavelength around 2.9 μm. The emission states can be finely tuned by engineering the geometries of the meta-atoms, as illustrated by the finite-difference time-domain (FDTD) simulations.

As shown in FIG. 3, the resonance wavelength can be tuned across a range of 2.9 μm to 4.8 μm as the side length of nanosquares changes from 500 nm to 750 nm (thereby changing the area of the upper surface of each nanosquare).

As described in Eq. (1), the thermal emission of a metasurface is generally controlled by its emissivity and local temperature. By integrating pixelated plasmonic metasurfaces with Gr-FETs, an integrated emissivity-temperature scheme to actively modulate coherent thermal emission from metasurfaces in the mid-infrared range is introduced. Specifically, the Gr-FETs precisely shift the heating position to the target pixel metasurface with a designated emissivity. Other than the size-dependent tuning of resonant wavelength shown in FIG. 3, the emissivity engineering of the customized meta-atoms, facilitated by the graphene infrared transparency, can be further demonstrated by tuning the polarization of the Au nanorods array.

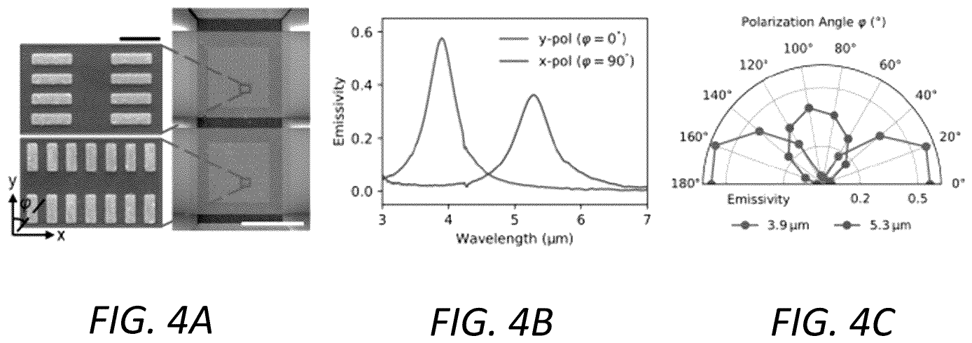

FIG. 4A illustrates two pixels composed of perpendicular Au nanorods with distinct lengths fabricated directly on a single graphene channel. In FIG. 4B, their measured length-dependent resonant spectra depicts one emission peak at 3.9 μm along polarization angle φ=0° and the other at 5.3 μm along φ=90°. As shown by the polar plot in FIG. 4C, the emission peaks of the two pixels are measured across a range of polarization angles from 0° to 180°, where two orthogonal polarization states are clearly observed.

The direct contact between the Au nanoantennas and graphene also enables tunable emissivity directly through an electrostatic gating (instead of switching the heating position) on the active metasurface, where the gating-induced carrier doping in graphene alters the dielectric environment for the LSPs from the Au nanoantennas. However, due to the limited carrier mobility of the CVD graphene, the resonance peak of the metasurface only undergoes a ^{~}0.5 μm blue shift from a gate voltage reaching the Dirac point of the graphene to considerably far from the Dirac point.

While the design based on LSP exhibits low temporal coherence due to strong non-radiative loss and low spatial coherence due to its local mode nature, plasmonic quasi-bound state in the continuum (P-QBIC) can also be used to improve both aspects. Due to the stationary and ergodic thermal fluctuations in equilibrium and quasi-homogeneous pixel emitter, temporal and spatial power spectral densities can be defined through the Wiener-Khinchin theorem (WKT) for the temporal and spatial coherences, respectively. While the temporal WKT directly connects the temporal coherence with the spectral bandwidth, under the far-field approximation, the spatial power spectral density can be expressed as the angular radiance distribution, which is thus related to the spatial coherence. Specifically, the coherence time and (transverse) coherence length for the metasurface thermal emitter can be quantified based on the uncertainty principle. A quasi-monochromatic source with bandwidth Δ_{ω} has a coherence time approximately equal to τ_{c}=2π/Δ_{ω}, and a quasi-parallel beam with a spatial frequency bandwidth |Δk_{∥}| has a transverse coherence length of L_{c}=2π/|Δk_{∥}|, where ∥ denotes the wavevectors in-plane. The P-QBIC mode originates from an ideal BIC mode generated by two counter-propagating Rayleigh anomalies or in-plane diffraction orders, based on two elliptical scatterers, and is then perturbed by a small tilt angle to achieve far-field emission in the normal direction. Two primary factors contribute to the enhancement of coherence: (1) the BIC nature of the mode suppresses radiative channels, substantially increasing the radiative quality factor and, consequently, improving temporal coherence; and (2) the mode's nonlocal character narrows the in-plane wavevector distribution, resulting in higher spatial coherence.

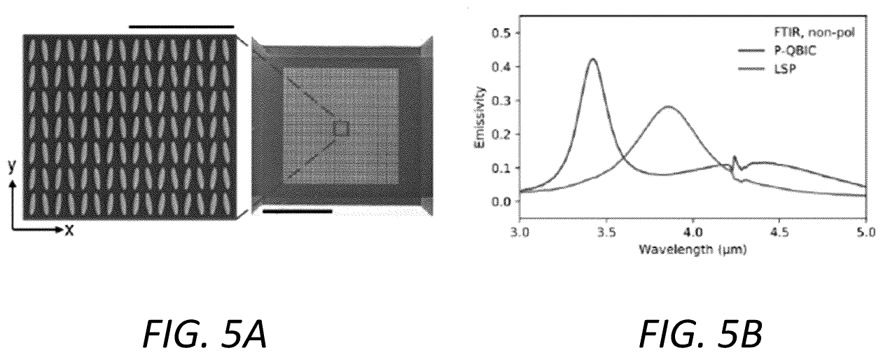

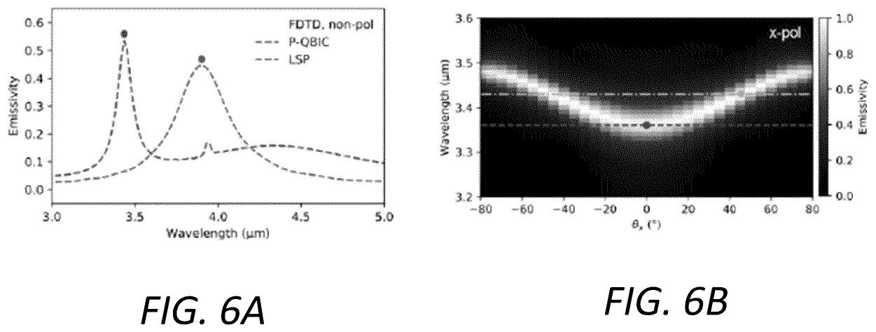

As shown in FIG. 5A, the P-QBIC design still follows an MIM structure and thus is well compatible with the pixelated array design and graphene tunable heaters. FIG. 5B shows that the P-QBIC mode exhibits substantially reduced spectral bandwidth relative to the LSP mode (corresponding to the lower pixel in FIG. 4A, indicating enhanced temporal coherence. The Fourier-transform infrared spectroscopy (FTIR) measurements agree well with the FDTD simulations for both modes, as illustrated in FIG. 6A. The FTIR spectra reveal a tiny emission peak at 4.2 μm attributed to atmospheric CO₂ absorption, which can be mitigated through N₂ purging during measurements.

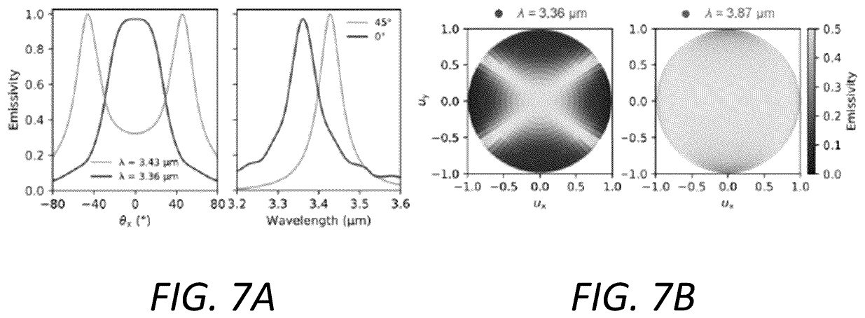

The FDTD simulations of the P-QBIC mode reveal a spurious peak at 3.9 μm from higher-order in-plane diffraction requiring perfect periodicity, which is absent in experimental FTIR spectra due to fabrication imperfection. To further quantify the coherence, the dispersion relation of the P-QBIC mode in the far field for the x-polarization is analyzed, as shown in FIG. 6B. Through emissivity mapping as a function of wavelength and polar angle along the x-axis θₓ from 0° to 80° (with fixed azimuthal angle φ=0°), a parabolic photonic band structure is observed. While the temporal and spatial coherences are linked and governed by the dispersion relation, they are analyzed separately to characterize their respective parameters, coherence time τ_{c} and coherence length L_{c}, by examining the fixed wavelength or θₓ spectra in FIG. 7A. The angular distributions for resonant wavelengths 3.36 μm and 3.43 μm, corresponding to the lower and upper dashed lines in FIG. 6B. The emissivity exhibits resonances at θₓ=0° (normal) and ±45°, with an angular spreading of Δθₓ=61° and 32°, resulting in coherent lengths of L_{c}=3.33 μm and 8.79 μm, respectively. Because the coherence lengths are comparable to and larger than the resonant wavelengths, the metasurface thermal sources hold partially local coherence. Then, the spectral distributions given the polar angles θx=0° and 45° are plotted, corresponding to the lower and upper dots in FIG. 6B. The bandwidth analysis reveals coherence times of τ_{c}=597 fs and 448 fs for 45° and 0° angles, respectively. These coherence times represent a substantial improvement compared to the 136 fs coherence time for the LSP mode. Finally, the angular spreading investigation was extended to encompass the full range of propagation angles at the resonant wavelength of 3.36 μm, including θ∈[0,80]° and φ∈[−180,180]′, effectively covering nearly the entire positive z-hemisphere. By introducing the direction cosines uₓ=sin θ cos φ and u_{y}=sin θ sin φ, the k-space (uₓ=kₓ/k₀, u_{y}=k_{y}/k₀) plot presented in FIG. 7B. can be constructed. This k-space representation facilitates a direct comparison between the P-QBIC and LSP modes, highlighting the significantly stronger spatial coherence of the P-QBIC mode, as confirmed by its considerably narrower angular spreading. Yet, four spokes are observed extending (uₓ, u_{y}) from (0,0) to (±0.6, ±0.5), which exhibit relatively large angular spreading, indicating reduced spatial coherence. This phenomenon is dependent on the impedance matching between the emitter and the far field, governed by the dispersion relation. Achieving high spatial coherence across all propagation angles necessitates advanced dispersion engineering techniques.

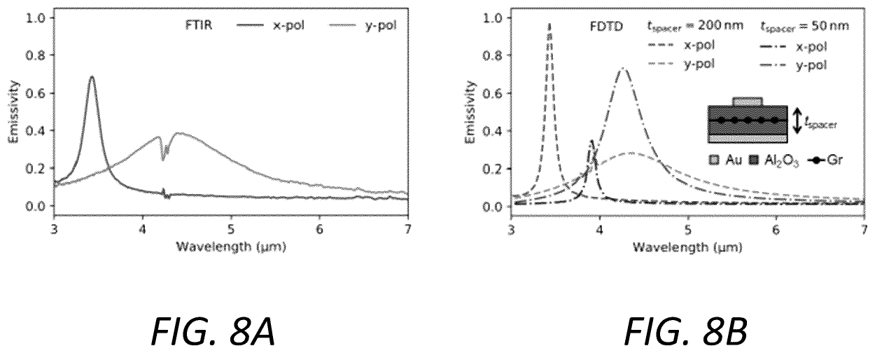

Additionally, a minor broad peak appears near 4.4 μm for the P-QBIC mode in FIG. 5B, corresponding to an additional LSP mode in the polarization orthogonal to the P-QBIC mode. The polarization-dependent FTIR spectra in FIG. 6A confirms this observation. Along the y-polarization, the long axis of the elliptical scatterer functions as a conventional LSP antenna, albeit slightly tilted. Its low emissivity stems from the large spacer thickness (200 nm) in the MIM structure, which optimizes the P-QBIC mode's impedance matching to the far field while leaving the LSP mode unmatched. This insight enables selective optimization of either the P-QBIC or LSP mode for narrowband or broadband applications, respectively. As demonstrated in FIG. 8B, with a 200 nm Al₂O₃ spacer, both polarized spectra align well with FTIR measurements, with the P-QBIC mode being dominant. Reducing the thickness to 50 nm causes the LSP mode to exceed the P-QBIC mode.

The Gr-FETs allow for programmable spatial temperature modulation because the semi-metallic nature of graphene enables fine tuning of its carrier density and channel resistivity through electrostatic gating. In contrast with traditional metal-based heating with a fixed resistance, the graphene-based tunable heaters can be more straightforwardly scaled up to a large-area on-chip 2D array with densely packed, independently controlled pixels, and potentially achieve a high speed due to the near-zero thermal mass of single-layer graphene. For a Gr-FET with a sole bottom gate electrode, the Joule heating reaches its maximum and generates a “hot-spot” at the position where the local resistivity of graphene is the highest. The local resistivity ρ(x) along the graphene channel can be expressed as:

$$ρ ( x ) = \sqrt{\frac{W}{2 {IC}_{o x} μ}} \cdot \frac{1}{\sqrt{sgn ( x - {x}_{o} ) \cdot ( x - {x}_{o} )}} \qquad ( 2 )$$

where:
W is the width of the graphene channel;
I is the steady channel current and is kept as constant along the graphene channel;
Cₒₓ is the gate dielectric capacitance per unit area;
μ is the carrier mobility that is approximated as constant;
x₀ is the position reaching the Dirac point; and
sgn is the sign function.

For the spatial temperature modulation from x=0 to L, we have:

$$\frac{sgn ( {x}_{0} - L )}{sgn ( {x}_{0} )} \sqrt{\frac{sgn ( L - {x}_{0} ) ( L - {x}_{0} )}{sgn ( - {x}_{0} ) ( - {x}_{0} )} = \frac{{V}_{Dirac} - {V}_{g}}{{V}_{Dirac} - {V}_{g} + {V}_{d}}} \qquad ( 3 )$$

where:
V_{g} is the gate voltage;
V_{d} is the drain voltage;
L is the channel length, and the source electrode is grounded; and
V_{Dirac} is the Dirac voltage corresponding to the neutrality point of graphene depending on its intrinsic doping and substrate.

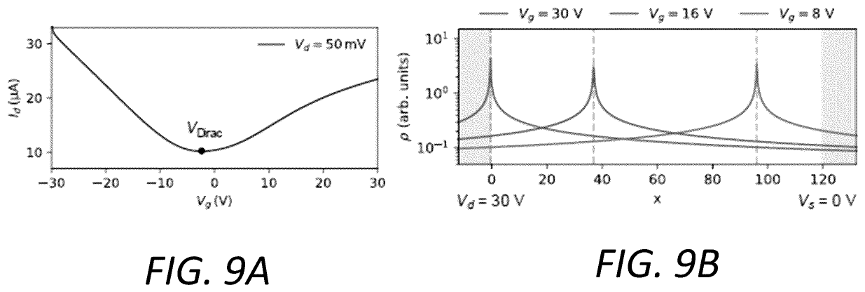

Hence, the hot spot on the Gr-FET can be controlled and continuously shifted in a programmable way by tuning V_{g} and V_{d}. As shown in FIG. 9A, a preliminary sweep of source-drain current versus gate voltage I_{d}−V_{g} is conducted for the Gr-FET under a low drain voltage V_{d}=50 mV (with the source electrode grounded) to determine the Dirac voltage V_{Dirac}=−2 V. By substituting Eq. (3) into Eq. (2) with the graphene channel length L=120 μm, and setting W/(2ICₒₓμ)=1 for simplicity, the local resistivity is plotted (in arbitrary units) as a function of gate voltage to demonstrate the shifting of the Dirac point, as shown in FIG. 9B.

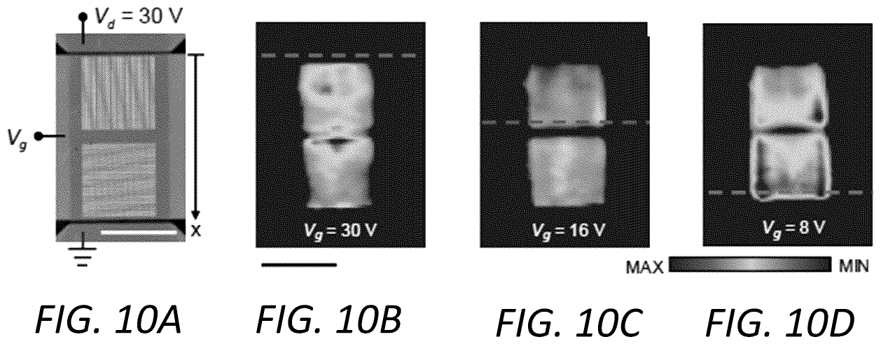

The observed Dirac point positions x₀ correlate well with the thermal mapping results, as indicated by the dash lines in FIGS. 10B-10D. FIG. 10A shows a metadevice composed of two pixels with identical resonant emission wavelengths along the graphene channel under a source-drain bias of V_{d}=30 V. When the gate voltage is v_{g}=30 V, the Dirac point position would lie outside the graphene channel region (i.e., x₀<0), thus resulting in a stronger illumination in the upper pixel, as shown in FIG. 10B. For v_{g}=16 V, the Dirac point lies in the gap between two pixels, and therefore the two pixels exhibit comparable but notably weaker thermal emission, as shown in FIG. 10C, compared to the scenarios at v_{g}=8 V and v_{g}=30 V due to its larger overall resistance of the Gr-FET. Finally, at v_{g}=8 V, the Gr-FET is expected to show the Dirac point at the position x₀=0.8 L, and thus the lower pixel exhibits stronger thermal infrared emission, as shown in FIG. 10D.

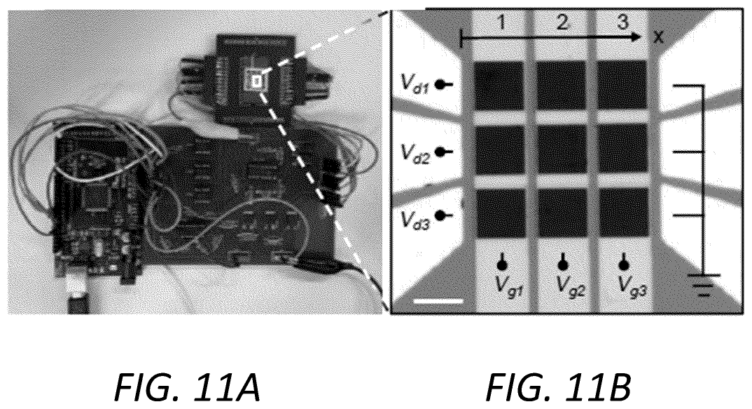

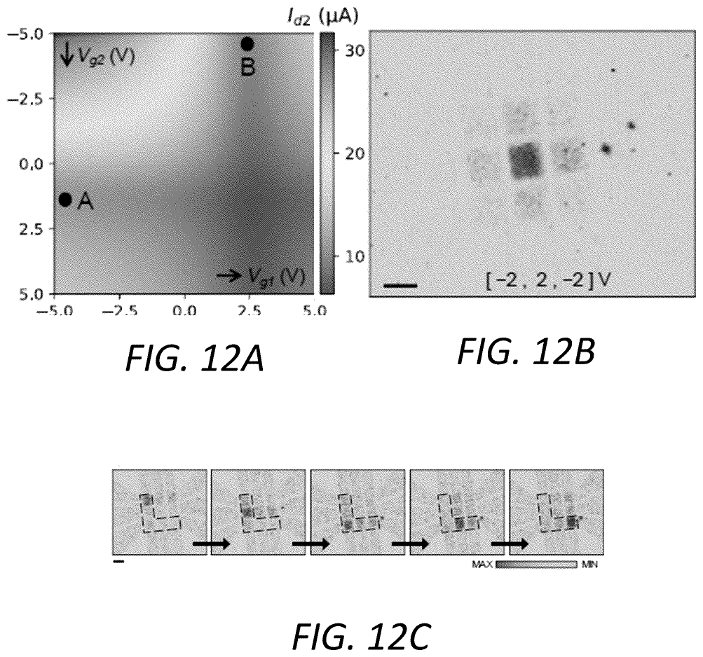

Pixelated 2D Array Dynamics with Regulated Emission-Now disclosed is an addressable pixelated active metasurfaces with separated local gate electrodes for each pixel. FIG. 11A shows an active metadevice integrated with a custom-designed printed circuit broad (PCB). In the zoomed-in view in FIG. 11B, the bottom gate electrode is distinctly partitioned into three segments, each specifically associated with one individual pixel. The control of each gate voltage is demonstrated in the sweep mapping of I_{d2}−(V_{g1}, V_{g2}) under V_{d2}=50 mV in FIG. 12A, where the gate electrode 3 is grounded (i.e., V_{g3}). For each value of the gate 1 voltage V_{g1}, the sweep of I_{d2}−V_{g2} for gate 2 maintains the bipolar transport characteristic curve of the Gr-FET (FIG. 9A). When V_{g2} is tuned for the V_{Direc} alignment for the pixel on/off, V_{g1} can be set to be away from V_{Direc}, as depicted by point A in FIG. 12A, to increase the overall current along the graphene channel for an enhanced pixel brightness. By symmetry, this strategy applies to the sweep of I_{d2}−V_{g1} under the control by V_{g2}, as labeled by point B in FIG. 12A. Through this methodology, the device has the capability not only to adjust the position of the heated pixel but also to regulate its heating intensity, which also indicates the pixel's brightness. The coupling between pixels can be described as 3 Gr-FETs in series whose Dirac point positions x₀₁, x₀₂, x₀₃ are given by:

$$\{ \begin{matrix}{V}_{g 1} - {V}_{g 2} = - sgn ( \frac{L}{3} - {x}_{02} ) \sqrt{sgn ( \frac{L}{3} - {x}_{02} ) C ( \frac{L}{3} - {x}_{02} )} + sgn ( \frac{L}{3} - {x}_{01} ) \sqrt{sgn ( \frac{L}{3} - {x}_{01} ) C ( \frac{L}{3} - {x}_{01} )} \\ {V}_{g 2} - {V}_{g 3} = - sgn ( \frac{2 L}{3} - {x}_{03} ) \sqrt{sgn ( \frac{2 L}{3} - {x}_{03} ) C ( \frac{2 L}{3} - {x}_{03} )} + sgn ( \frac{2 L}{3} - {x}_{02} ) \sqrt{sgn ( \frac{2 L}{3} - {x}_{02} ) C ( \frac{2 L}{3} - {x}_{02} )} \\ {V}_{Dirac} - [ {V}_{g 1} - {V}_{d} ] = - sgn ( 0 - {x}_{01} ) \sqrt{sgn ( 0 - {x}_{01} ) C ( 0 - {x}_{01} )} \\ {V}_{Dirac} - [ {V}_{g 3} - 0 ] = - sgn ( L - {x}_{03} ) \sqrt{sgn ( L - {x}_{03} ) C ( L - {x}_{03} )}\end{matrix}$$

The resistance Rᵢ for each pixel i=1,2,3 can then be derived by integrating the local resistivity Eq. (2) using the inputs x₀₁, x₀₂, x₀₃ for each segment. At V_{d2}=5 V, FIG. 12B employs [V_{g1}, V_{g2}, V_{g3}]=[−2, 2, −2] V to light up the central pixel with the computed resistances as [R₁, R₂, R₃]=[529, 1877, 1023] Ω. The addressable pixelated operation can be readily scaled up to a large-area 2D array for real-world applications. FIG. 12C demonstrates a 3×3 pixelated display showing letter “L” by electrically programming individual frames. Various letter or number patterns can be generated using distinct pixel sweep schemes. These display demonstrations by independent pixel control use only 7 electrical pins (a total of 2N+1 pins with 3 gate electrodes, 3 drain electrodes, and 1 grounded source electrode), fewer than 9 pins (corresponding to N² pins) conventionally installed. This advantage becomes more pronounced as the number of pixels increases.

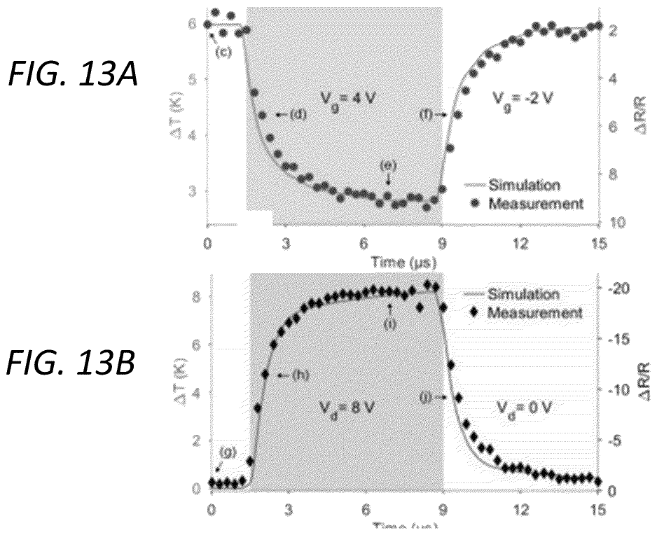

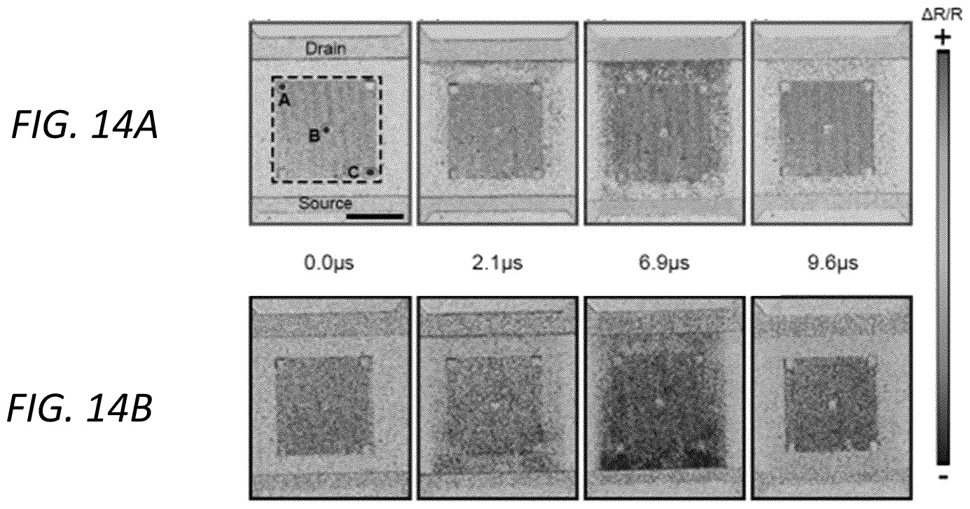

Transient Thermal Mapping of Pixel Modulation—To quantitatively understand the response speed of an individual pixel in the 2D array displaying dynamic infrared patterns via pixel sweeping, thermal transient simulations are performed on a single pixel device, where transient responses of temperature change (ΔT) due to voltage modulations are collected. Such responses are then verified by the reflectivity change (ΔR/R) measured via time-domain thermoreflectance temperature mapping on a fabricated single pixel device. Here two modulation schemes are demonstrated: (1) gate-voltage modulation using a single gate voltage pulse V_{g}=4 V with constant drain voltage V_{d}=6 V and grounded source electrode to change the relative brightness of each pixel, and (2) source-drain-voltage on/off modulation using a single drain voltage pulse V_{d}=8 V with constant grounded V_{g} to activate and deactivate each pixel row. The pulse width of both modulations is set as 7.5 μs, and the monolayer graphene is measured to have the Dirac point about V_{Dirac}=1.4 V. FIGS. 13A-13B show the simulated and experimental transient response curve of the two modulations, capturing each time frame of the surface temperature and reflectivity changes by averaging the whole nanoantenna array area, as indicated by the dashed-line box in the leftmost frame of FIG. 14A.

For the gate-voltage modulation shown in FIG. 13A, initial V_{g}=−2 V is provided at time t=0 μs. Applying boundary conditions of V(0)=V_{d} and V(L)=Vₛ, analytical calculation gives the Dirac point location x₀>L and electrical current I=8.7 mA, indicating that the whole graphene channel is at the hole dominant region resulting in a relatively low total resistance (FIG. 14A). When t reaches 1.5 μs, V_{g} is set to 4 V. As a result, x₀=0.63 L and I=2.1 mA, hence such reduced current causes a reduction of heat generation and a drop in the average temperature. The ongoing increases of reflectance difference ΔR/R with V_{g}=4 Vat t=2.1 μs and t=6.9 μs are captured on mapping photos in the middle frames of FIG. 14A, corresponding to temperature decreases across the channel. These thermoreflectance mappings also depict the spatial temperature modulation, where the location of the Dirac point x₀=0.63 L near the source (bottom) electrode is implied by a smaller ΔR/R value and verified by simulation. Finally, at t=9 μs, V_{g} switches back to −2 V, which brings the heat generation pattern back to the initial condition. The surface temperature rises again while magnitude of ΔR/R decays, as shown by the overall fainted red color in the rightmost frame of FIG. 14A. In the full cycle of temperature falling and rising, the 10% to 90% fall time and rise time are measured to be t_{f1}=2.3 μs and tᵣ₁=2.4 μs, respectively. Similar procedures are followed for source-drain voltage on/off modulation as shown in FIG. 13B where V_{g} and the source electrode are kept grounded, V_{d} is set to 0 V at t=0 μs, up to 8 V at t=1.5 μs, and back to 0 V at t=9 μs. The temperature rising and falling profile and reflectivity change are captured to have satisfactory match of each other, with tᵣ₂=1.9 μs and t_{f2}=2.3 μs. FIG. 14B shows typical mapping photos at the same time frames as FIG. 14A. It is worth noting that at t=6.9 μs, the third frame of FIG. 14B depicts a hot spot near the source (bottom) electrode as an intensified blue color, which is also verified by simulation and analytical modeling. The response speed of the electrothermally driven metasurface is limited by its speed of thermal dissipation to the substrate. A lumped-capacitance thermal circuit model is applied, which is related to the 10% to 90% rise time Ty by f_{c}=0.35/τᵣ, to obtain the 3-dB cutoff frequencies for the gate-voltage modulation as f_{c1}=146 kHz and for the source-drain-voltage on/off modulation as f_{c2}=184 kHz. The device speed can potentially reach MHz-level by optimizing the substrate design and the size of metasurface for heat transfer.

Dual-Gate Pixelated Array for Low Crosstalk—Although the feasibility of 2D temperature tuning using Gr-FET arrays has been successfully demonstrated, thermal crosstalk occurs by heat generation in the device because the graphene pixel transistors cannot be turned off completely. On the one hand, graphene generates significant heat due to its semi-metallic nature, exhibiting higher conductivity compared to other 2D semiconductors such as Mos₂, which can also be synthesized through CVD growth. On the other hand, achieving a sufficient on/off ratio in transistors requires a material with an adequate bandgap. In principle, bandgap engineering in graphene can be achieved through bilayer stacking or quantum-scale patterning to modify its electronic band structure. However, these techniques present significant technical difficulties and stability issues, particularly when implemented at large scales.

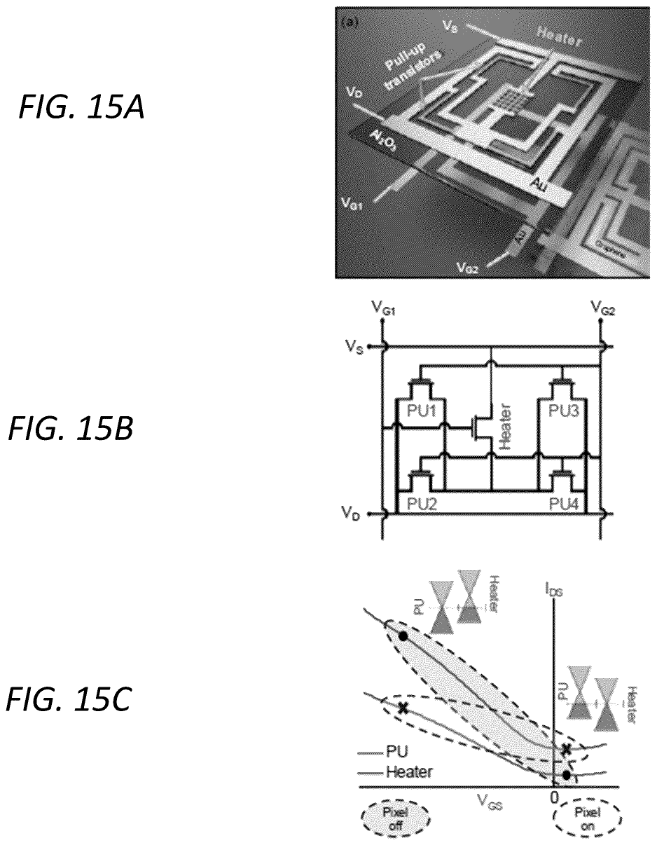

To address such limitations, disclosed herein is a pull-up (PU) transistor configuration as a dual-gate pixelated array for low crosstalk. As illustrated in FIG. 15A, each individual pixel consists of a center heating Gr-FET (heater) with metasurfaces deposited on the top, and four “L” shaped PU Gr-FETs encircling the heater. The 4 PUs are connected in parallel to the drain line (V_{D}) and are controlled by a shared gate electrode (V_{G2}) to form a unified PU transistor, which is then connected in series to the drain electrode of the heater controlled by a separate gate electrode (V_{G1}), whose source electrode is connected to the source line (V_{S}), as shown in FIG. 15B. Such design allows pixels to be arranged into 2-D arrays by sharing common source lines and drain lines in parallel in the same row and control gates in the same column.

The separation of PU transistors with their geometry design optimizes the uniformity of substrate temperature distribution and keeps residual heat generated by the PUs away from the heater, hence minimizing their thermal influence. The on/off operation of one pixel is realized by varying V_{G1} and V_{G2} while keeping the V_{S} and V_{D} constant so that adjacent pixels on the same row will not be affected. As illustrated in FIG. 15C, when the pixel is at an off state, the PU transistors, which are geometrically designed to have larger intrinsic channel resistance, are further charge-depleted by varying V_{G2}, hence moving the Fermi level EF to the Dirac point so that their resistance maximum is reached, and the channel current I_{DS} is reduced. On the contrary, the heater is negatively gated towards hole-doped direction and its channel resistance is further decreased. Such operation enlarges the channel resistance contrast between the PUs and the heater, thereby minimizing the voltage drop and power distribution on the heater. On the other hand, when the pixel is turned on, the channel resistance contrast between the PUs and the heater is reversed, with the PUs changing to a low-resistance state, pulling up the drain voltage for the heater, and the heater changes to its high-resistance state which is more resistive than that of the PUs, maximizing its power dissipation and therefore leading to a large temperature rise. Finally, the metasurface emitter is selectively placed only in the pixel area, while the PUs maintain low emissivity from graphene. This spatial emissivity contrast, combined with the temperature contrast discussed above, enhances the overall IR emission contrast.

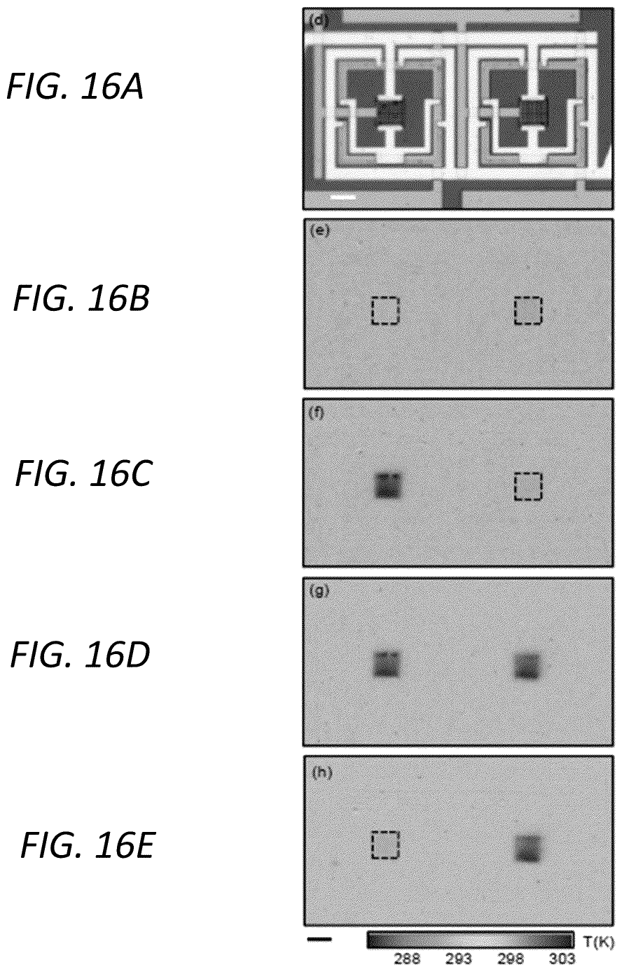

To validate such an on/off operation, a one-by-two pixel array is fabricated, as shown by the optical 366 microscope image in FIG. 16A. Each pixel has a side length of 120 μm, and the center heater has a size of 20 μm×20 μm. During operation, the source line is grounded (V_{S}=0 V) and the drain line is applied a constant V_{D}=5 V. When V_{G1}=−9 V and V_{G2}=3 V for both pixels, dual off states are obtained and measured via thermal mapping, shown in FIG. 16B. Since metasurfaces are only deposited on top of the heater, IR emission noise from the PU transistors with bare graphene is suppressed and becomes approximately invisible to an IR camera. Compared with the substrate temperature, the heater is measured to have only around 0.6 K temperature rise, making it nearly indistinguishable from the surroundings. To turn on the left pixel, the gate voltages of the left pixel is changed to V_{G1}=1.5 V and V_{G2}=6 V. It can then be monitored that the temperature of the left heater rises by more than 5 K, while the right pixel remains unaffected, as shown in FIG. 16C. Similarly, by switching the gate voltage combinations, both on (FIG. 16D) or right-on/left-off (FIG. 16E) configurations can be achieved. It can be observed that such a design improves the temperature contrast between on and off states by adding PU transistors to redistribute the power on each pixel. The dual-gate pixel design holds the number of pins as 3N+1 (including 2N gate electrodes, N drain electrodes, and 1 grounded source electrode), and it is still far fewer than the N² number in the conventional design.

Device Fabrication-Monolayer graphene is synthesized via low-pressure chemical vapor deposition (LPCVD) on a 99.9% pure Cu foil. The Cu foil is polished via electrochemical polishing in 85% phosphoric acid for 2.5 hours. It is then cleaned by deionized water and moved into an LPCVD quartz tube furnace. 4-hour hydrogen annealing is performed with 140 standard-cubic-centimeter per minute (sccm) hydrogen flow until a pressure of 4 torr is stabilized. 3 sccm methane and 137 sccm hydrogen mixing gas is then used to grow monolayer graphene on the Cu substrate for 30 minutes, while the pressure is kept the same. Finally, the furnace is opened for a rapid cooling with 140 sccm hydrogen gas purging until room temperature is reached.

The Gr-FET is fabricated on a Si/1 μm-SiO₂ wafer diced into 9 mm×9 mm chips. The bottom gate electrodes are patterned using a lift-off method: firstly, photolithography is performed with AZ P4110 photoresist; then, the gate metal is deposited via e-beam evaporation of 50 nm thick Au with 2 nm Ti adhesion layer; lastly, Microposit remover 1165 is used to remove the photoresist. After the Al₂O₃ layer is deposited via thermal atomic-layer deposition (ALD) under 250° C., the CVD-synthesized monolayer graphene is transferred using the PMMA-assisted wet transfer method and patterned to a desired shape via reactive-ion etching (RIE). Au metasurfaces with various thicknesses are patterned on top of the graphene layer via e-beam lithography using PMMA as the e-beam resist followed by e-beam evaporation of Au with a 2 nm Ti adhesion layer. The thicknesses t₁ for the gate dielectric separating the gate electrode (also underneath mirror) and graphene layer and t₂ for the separation between the graphene layer and the Au metasurface are summarized for each device: (t₁=20 nm, t₂=10 nm) for FIGS. 1B, 11B, 14A, 14B (t₁=20 nm, t₂=0 nm) for FIG. 2; (t₁=150 nm, t₂=50 nm) for FIG. 5A; (t₁=100 nm, t₂=10 nm) for FIG. 10A; (t₁=40 nm, t₂=10 nm) for FIG. 15A. Finally, the source and drain electrodes are patterned using the same method as the gate electrodes.

In summary, disclosed herein is a pixelated electrically driven plasmonic metasurface integrated with a Gr-FET for dynamic coherent mid-infrared emission. The customized design of plasmonic nanoantennas, including LSP and P-QBIC, in combination with the ultrabroad infrared transparency of graphene enables tuning of different coherent states, including resonant wavelengths, directions, and polarizations. The 2D pixelated high-speed dynamics is achieved by integrating the emissivity control with the spatial temperature tuning by the Gr-FET, with the bandwidth of about 146 kHz in low crosstalk. With the highly dynamic control of electromagnetic responses in the infrared range, the disclosed implementation of graphene-integrated active metasurfaces has important implications in infrared lab-on-a-chip, chemical and biological sensing, personalized health monitoring, and portable real-time beam shaping and steering.

As would be realized by one of skill in the art, many variations on implementations discussed herein which fall within the scope of the invention are possible. Specifically, many variations of the materials, the components used and their arrangement could be used to obtain similar results. The invention is not meant to be limited to the particular exemplary embodiments disclosed herein. Moreover, it is to be understood that the features of the various embodiments described herein were not mutually exclusive and can exist in various combinations and permutations, even if such combinations or permutations were not made express herein, without departing from the spirit and scope of the invention. Accordingly, devices disclosed herein are not to be taken as limitations on the invention but as an illustration thereof.

1. A metasurface device, comprising:
a plurality of pixels, each pixel comprising:
an array of plasmonic nano-antennas;
a layer of graphene patterned into a plurality of Gr-FETs having source and drain contacts and corresponding to the pixels.

2. The metasurface device of claim 1, further comprising:
a layer of aluminum oxide separating each pixel from its corresponding Gr-FET.

3. The metasurface device of claim 1 wherein the plasmonic nano-antennas are composed of gold.

4. The metasurface device of claim 1 wherein the source and drain of each Gr-FET are composed of gold.

5. The metasurface device of claim 1 wherein each pixel is independently addressable.

6. The metasurface device of claim 1 wherein a resonance wavelength of each pixel is a function of the area of an upper surface of each plasmonic nano-antenna.

7. The metasurface device of claim 1 wherein an emission wavelength peak of each pixel is a function of polarization of the nano-antennas in each respective pixel.

8. The metasurface device of claim 1 wherein the device is operated in a localized surface polariton (LSP) mode.

9. The metasurface device of claim 1 wherein the device is operated in a plasmonic quasi-bound state in the continuum (P-QBIC) mode.

10. The metasurface device of claim 1 wherein each Gr-FET has a hotspot and further wherein a position of the hotspot of each Gr-FET can be controlled by tuning the gate and drains voltages.

11. The metasurface device of claim 10 wherein the gate voltage can be used to shift the Dirac point voltage of the Gr-FET.

12. The metasurface device of claim 1 further comprising:
a plurality of pull-up transistors surrounding a central Gr-FET acting as a heater.

13. The metasurface device of claim 12 wherein the plurality of pull-up transistors are connected in parallel to the drain of the Gr-FET and are controlled by a shared gate electrode to form a unified pull-up transistor.

14. The metasurface device of claim 12 wherein the plurality of pull-up transistors comprises 4 transistors.

15. The metasurface device of claim 13 wherein unified pull-up transistor is connected in series with the drain of the Gr-FET.
